(19) United States
(12) Patent Application Publication
(10) Pub. No.: US 2026/0297739 A1
(43) Pub. Date: Oct. 1, 2026

(54) COLLECTING APPARATUS AND COLLECTING METHOD

(71) Applicant: JUSUNG ENGINEERING CO., LTD., Gwangju-si, Gyeonggi-do (KR)

(72) Inventors: Ji Hong HAN, Gwangju-Si, Gyeonggi-do (KR); Seung Youb SA, Gwangju-Si, Gyeonggi-do (KR); Sang Hyuk LEE, Gwangju-Si, Gyeonggi-do (KR); Dae Soo JANG, Gwangju-Si, Gyeonggi-do (KR); Chul Joo HWANG, Gwangju-Si, Gyeonggi-do (KR)

(21) Appl. No.: 19/167,425

(22) PCT Filed: Feb. 19, 2024
(86) PCT No.: PCT/KR2024/095378

§ 371 Date: Sep. 22, 2025

(30) Foreign Application Priority Data
Mar. 21, 2023 (KR) 10-2023-0036663

(51) Int. Cl. C23C 16/44; B01D 53/00; C23C 16/18; C23C 16/40; C23C 16/455

(52) U.S. Cl. CPC C23C 16/4412; B01D 53/002; C23C 16/18; C23C 16/40; C23C 16/45544; B01D 2257/706; B01D 2258/0216

(57) ABSTRACT

The embodiments of the present invention relate to a collecting apparatus for collecting a precursor from exhaust gas discharged from a processing apparatus using the precursor. The collecting apparatus may comprise a first collector which is equipped with: a cooling part which has a first refrigerant passing therethrough so as to enable cooling and recovering exhaust gas; and an inner space which is connected to a processing apparatus and is controllable by means of vacuum pressure. Thus, according to the embodiments of the present invention, a precursor may be effectively collected from the exhaust gas discharged from the processing apparatus. That is, collecting efficiency for the precursor collected from the exhaust gas may be improved. Thus, the amount of the precursor that is discarded may be reduced. In addition, the collected precursor may be reused in the processing apparatus, and thus costs arising from the precursor may be reduced.

### TECHNICAL FIELD

The present disclosure relates to a collecting device and a collecting method, and more particularly, to a collecting device that is collects a precursor from an exhaust gas discharged from a process device using the precursor, and a collecting method.

### BACKGROUND ART

A deposition device that deposits a thin film on a substrate uses a precursor as a raw material gas. That is, when an injection part of the deposition device injects a precursor gas into a chamber, the thin film is deposited on the substrate. A pump is connected to the chamber of the deposition device, and the pump exhausts the inside of the chamber.

In the precursor injected into the chamber, a precursor that fails to react inside the chamber or is not deposited on the substrate are exhausted to the outside of the chamber during the exhaustion. In addition, the exhausted expensive precursor is discarded. Then, during the next deposition process, a new precursor is supplied to the deposition device, and the deposition device performs the thin film deposition using the newly supplied precursor. Therefore, there is a limitation that costs of preparing the precursor increase.
[Prior Art Document] (Patent Document 1) Korean Patent Publication No. 10-2008-0020953

### DISCLOSURE OF THE INVENTION

### Technical Problem

The present disclosure provides a collecting device capable of effectively collecting a precursor from an exhaust gas discharged from a process device using the precursor, and a collecting method.

### Technical Solution

In accordance with an exemplary embodiment, a collecting device, which collects a precursor from an exhaust gas discharged from a process device using the precursor, includes: a first collector provided with a cooling part, through which a first coolant passes, so the exhaust gas is cooled to be recovered and having an internal space connected to the process device so as to be adjusted to a vacuum pressure.

The collecting device may include a second collector provided with an injection member configured to inject a second coolant to the exhaust gas and disposed at one side of the first collector.

The first collector may be installed between one end of a pump connected to the process device and the process device, and the second collector may be connected to the other end of the pump.

The cooling part may include a body and a passage provided in the body so that the first coolant passes therethrough, and wherein the body may include: a first body extending upward; and a plurality of second bodies disposed to be spaced apart from each other in a vertical direction on an outer surface of the first body.

The plurality of second bodies disposed adjacent to each other in the vertical direction may be disposed to be misaligned in a horizontal direction.

Each of the second bodies may be provided to be inclined so that a height thereof decreases as it moves away from the first body.

The first collector may include: a housing part in which the cooling part is installed therein; an accommodation part connected to a lower portion of the housing part to accommodate the precursor recovered from the housing part; and an opening/closing part installed in the housing part so as to be disposed between the cooling part and the accommodation part.

The accommodation part may include: a body connected to a lower portion of the housing part; and a container having an internal space in which the recovered precursor is accommodated and installed inside the body, and the first collector may include: a measurement part configured to detect the precursor accommodated in the container; and a determination part configured to determine whether replacement of the container is required depending on a measured value measured in the measurement part.

The housing part may include: a first housing connected to the process device; and a second housing connected to the first housing in a horizontal direction so as to communicate with the first housing, wherein the second housing may be configured to connect the first housing to the pump, and the cooling part may be installed in each of the first housing and the second housing.

The housing part may include a connection housing configured to connect the first housing to the second housing, and the first collector may include a partition wall installed inside the connection housing so as to be provided with a passage, through which the first coolant flows, is provided therein and partially shield the inside of the connection housing.

The partition wall may be provided in plurality, and the plurality of partition walls may be disposed at different positions inside the connection housing.

The second collector may include: a body having an internal space, in which the second coolant injected from the injection member is accommodated, and the injection member is installed; and a container disposed below the injection member to accommodate the precursor, which is recovered from the exhaust gas inside the body, and the second coolant.

The second collector may include: a measurement part configured to detect the precursor and the second coolant, which are accommodated in the container; and a determination part configured to whether to discharge the precursor and the second coolant, which are accommodated in the container, depending on a measured value measured in the measurement part.

An outlet communicating with a scrubber to discharge the exhaust gas may be provided in an end of the body, and the second collector may include a blocking member installed inside the body to face the outlet so that the second coolant injected into the body is discharged through the outlet.

The blocking member may be installed between the injection member and the outlet, and the blocking member may be installed to be inclined so that a height thereof decreases from the outlet toward the injection member.

In accordance with another exemplary embodiment, a substrate processing apparatus includes: a chamber having an internal space; a support configured to support a substrate inside the chamber; a supply part configured to supply a gas containing a precursor into the chamber; and a first collector provided with a cooling part, through which a first coolant passes, to recovery the precursor contained in an exhaust gas discharged from the chamber and having an internal space communicating with the chamber so as to be adjusted to a vacuum pressure.

The collecting device may include a second collector provided with an injection member configured to inject a second coolant to the exhaust gas and disposed at one side of the first collector.

The substrate processing apparatus may further include a pump installed between the first collector and the second collector to adjust a pressure of the chamber and the first collector to a vacuum pressure.

In accordance with yet another exemplary embodiment, a collecting method for collecting a precursor from an exhaust gas discharged from a process device using the precursor includes: a first collection process of recovering the precursor by allowing the exhaust gas to pass through a first passage in which a cooling part, through which a first coolant passes, is installed.

The method may further include a second collection process of recovering the precursor by allowing the exhaust gas discharged from the first passage to pass through a second passage through which a second coolant is injected.

A temperature of the first coolant may be 10° C. or less.

The first collection process may include a process of collecting the recovered precursor into a container.

The method may further include: a process of detecting the precursor collected into the container; a process of determining whether to replace the container depending on the detected result; and a process of replacing the container when it is determined that the replacement of the container is required, wherein the process of replacing the container may be performed while the first collection process is not performed by stopping an operation of the process device.

The process of determining whether to replace the container may include a process of comparing the detected result with a preset reference value.

The second collection process may include a process of collecting the precursor recovered from the second passage and the second coolant injected into the second passage into the container.

The method may further include a process of detecting the precursor and the second coolant,
which are collected into the container, wherein whether to discharge the precursor and the second coolant, which are collected into the container, may be determined by comparing the detected result with a preset reference value.

### Advantageous Effects

In accordance with the exemplary embodiments, the precursor may be effectively collected from the exhaust gas discharged from the process device. That is, the collection efficiency of the precursor collected from the exhaust gas may be improved. Therefore, the amount of precursor to be discarded may be reduced. In addition, the collected precursor may be recycled again in the process device to reduce the costs due to the precursor.

### BRIEF DESCRIPTION OF THE DRAWINGS

FIG. 1 is a conceptual view illustrating a state in which a collecting device is installed between a process device and a scrubber in accordance with an exemplary embodiment;

FIG. 2 is a view of the collecting device in accordance with an exemplary embodiment;

FIG. 3 is a view illustrating a first collector of the collecting device in accordance with an exemplary embodiment;

FIG. 4 is a view of a first cooling part, a second cooling part, a first partition wall, a second partition wall, and a a coolant transfer line connected to the first cooling part, the second cooling part, the first partition wall, and the second partition wall, which are coolant circulating components, in accordance with an exemplary embodiment; and

FIG. 5 is a view of a second collector in accordance with an exemplary embodiment.

### MODE FOR CARRYING OUT THE INVENTION

Hereinafter, specific embodiments will be described in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. In the figures, the dimensions of layers and regions are exaggerated for clarity of illustration. Like reference numerals refer to like elements throughout.

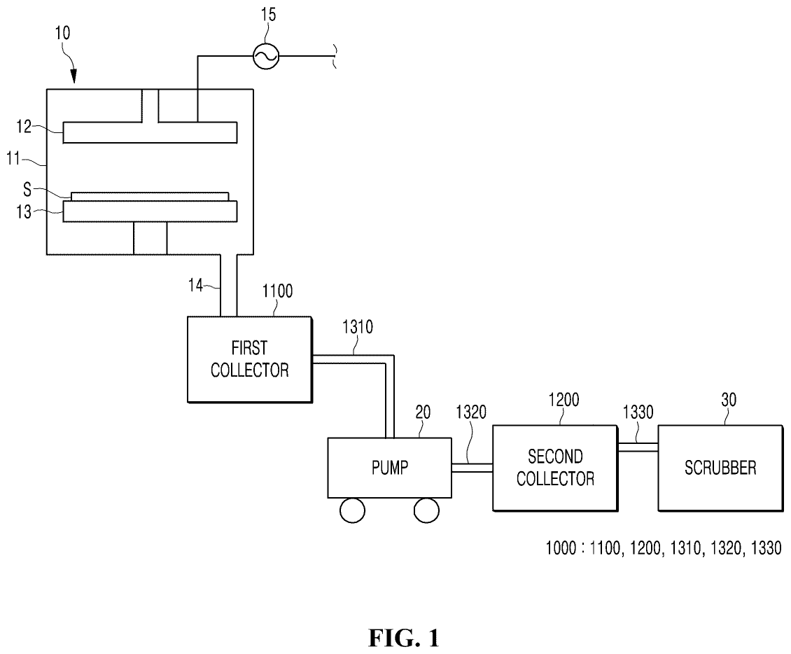

FIG. 1 is a conceptual view illustrating a state in which a collecting device is installed between a process device and a scrubber in accordance with an exemplary embodiment.

Embodiments relate to a collecting device that collects an exhaust gas discharged from a process device. In more detail, embodiments relate to a collecting device that is capable of cooling and collecting an exhaust gas discharged from a process device. Here, the exhaust gas discharged from the process device may be a precursor, which is a raw material for depositing a thin film on a substrate. The precursor may be a material containing a precious metal. The precious metal may be at least one of ruthenium (Ru), silver (Ag), gold (Pt), palladium (Pd), rhodium (Rh), iridium (Ir), and osmium (Os), and the precious metal is limited to the above materials.

Hereinafter, the precursor containing ruthenium (Ru), i.e., a ruthenium (Ru)-containing precursor, will be described as an example. As a result, the exhaust gas may be a gas containing ruthenium (Ru).

First, the process device 10 will be described with reference to FIG. 1. The process device 10 may be a deposition device that deposits a thin film on the substrate S. In addition, the process device 10 may be a deposition device capable of depositing a thin film containing ruthenium (Ru) on the substrate S. In more detail, the process device 10 may be a device that deposits a ruthenium (Ru) thin film on the substrate S using an atomic layer deposition (ALD) method. Here, the thin film containing ruthenium (Ru) may be at least one of a ruthenium (Ru) metal thin film, a ruthenium oxide (RuO₂) thin film, a ruthenium nitride (RuN) thin film, and a ruthenium oxynitride (RuON) thin film.

The process device 10 may include a chamber 11 having an internal space, a support installed inside the chamber 11 to support the substrate S on one surface thereof, a supply part disposed inside the chamber 11 to face the support 13 so as to supply a gas for the deposition process, and an exhaust part 14 connected to the chamber 11. In addition, the process device 10 may include a power supply part 15 that applies power for generating plasma, and the power supply part 15 may be connected to, for example, any one of the supply part 12 and the support 13.

The exhaust part 14 is connected to a pump 20 installed outside the chamber 11. The pump 20 may be a device capable of generating suction force, for example, a vacuum pump. Thus, when the pump 20 operates to generate the suction force, the gas inside the chamber 11 is discharged or exhausted to the outside. That is, the gas inside the chamber 11 is discharged toward the pump 20 through the exhaust part 14.

Hereinafter, the operation of the process device 10 will be described. Here, the operation of depositing the thin film containing ruthenium (Ru) on the substrate S using the atomic layer deposition (ALD) method will be described. In addition, the deposition of the ruthenium oxide (RuO₂) thin film on the substrate S will be described as an example.

First, a precursor containing (or including) ruthenium (Ru) is supplied to the substrate S using the supply part 12. That is, the ruthenium (Ru)-containing precursor is supplied into the chamber 11. Here, the ruthenium (Ru)-containing precursor may be in the form of a gas and may be a raw material or source for the thin film deposition. Thus, a process of supplying the ruthenium (Ru)-containing precursor may be described as a ‘raw material gas supply process’ or a ‘source gas supply process’. The ruthenium (Ru)-containing precursor may be, for example, ethylcyclopentadienyl ruthenium ((EtCp)₂Ru)(Bis(ethylcyclopentadienyl)ruthenium). Thus, when the ruthenium (Ru)-containing precursor is supplied to the substrate S, the ruthenium (Ru)-containing precursor is adsorbed or deposited on the substrate S to form the ruthenium (Ru) thin film. That is, the ruthenium (Ru) metal thin film is formed. When the supply of the precursor is completed, a purge gas such as argon (Ar) gas is supplied into the chamber 11 using the supply part 12 to perform first purge (first purge process). Next, a reaction gas containing oxygen is supplied to the substrate S on which the ruthenium (Ru) metal thin film is formed using the supply part 12 (reaction gas supply process). Here, the reactive gas may be an oxygen (O₂) gas. Thus, the ruthenium (Ru) metal thin film reacts with oxygen (O₂), and thus, as the ruthenium (Ru) metal thin film is oxidized, the ruthenium oxide (RuO₂) thin film is formed. When the supply of the reaction gas is terminated, a purge gas such as argon (Ar) gas is supplied into the chamber 11 using the supply part 12 to perform second purge (second purge process).

A process cycle for forming the ruthenium oxide (RuO₂) thin film may include the above-described ‘raw material gas supply process-first purge process-reaction gas supply process-second purge process’. In addition, the process cycle may be repeated several times to form the ruthenium oxide (RuO₂) thin film at a target thickness.

While forming the ruthenium oxide (RuO₂) thin film on the substrate S using the above-described process cycle, the pump 20 operates to control a pressure inside the chamber 11. That is, while performing the process cycle, the pump 20 operates to exhaust the gas inside the chamber 11 so as to control the pressure inside the chamber 11. Here, the gas discharged to the outside of the chamber 11 may include the ruthenium (Ru)-containing precursor that is not adsorbed to the substrate S. In more detail, the exhaust gas may contain ruthenium (Ru). In addition, when the ruthenium (Ru)-containing precursor that has not been adsorbed to the substrate S is discharged to the outside of the chamber 11, the largest amount of precursor may be exhausted in the first purge process that is performed after the row material gas supply process of the ‘raw material gas supply process-first purge process-reaction gas supply process—second purge process’. In addition, the exhaust gas discharged from the chamber 11 is transferred to a scrubber 30 and is discarded after removing dust from the scrubber 30.

As described above, the exhaust gas discharged from the process device 10 includes the ruthenium (Ru)-containing precursor that is not adsorbed on the substrate S. However, the ruthenium (Ru)-containing precursor is discarded without being collected. That is, expensive ruthenium (Ru) is discarded without being collected.

Therefore, in the present disclosure, a collecting device 1000 is installed between the process device 10 and the scrubber 30 to collect ruthenium (Ru) from the exhaust gas discharged from the process device 10. Here, the ruthenium-containing precursor (Ru) or ruthenium (Ru) contained in the exhaust gas may exist, for example, in a gaseous state. In addition, the collecting device 1000 in accordance with an exemplary embodiment cools the exhaust gas discharged from the process device 10 to collect the ruthenium (Ru) contained in the exhaust gas. That is, the exhaust gas is cooled to cool the ruthenium (Ru) contained in the exhaust gas, thereby collecting ruthenium (Ru). Here, that collecting of the ruthenium (Ru) may mean that cools the gaseous ruthenium (Ru) contained in the exhaust gas to transform the ruthenium (Ru) into solid particles or turn into a powder state. In addition, the cooling of the gaseous ruthenium (Ru) contained in the exhaust gas to turn into powder may mean that recovers the gaseous ruthenium (Ru) contained in the exhaust gas into the powder.

Hereinafter, the ruthenium that is in the powder state, which is generated by cooling the exhaust gas or the ruthenium recovered in the powder state will be described using the reference numeral ‘P’.

The powder-state precursor collected by a method in accordance with exemplary embodiments of the present disclosure may be recycled as the raw material, that is, the precursor, for depositing the thin film on the substrate S after subsequent processing.

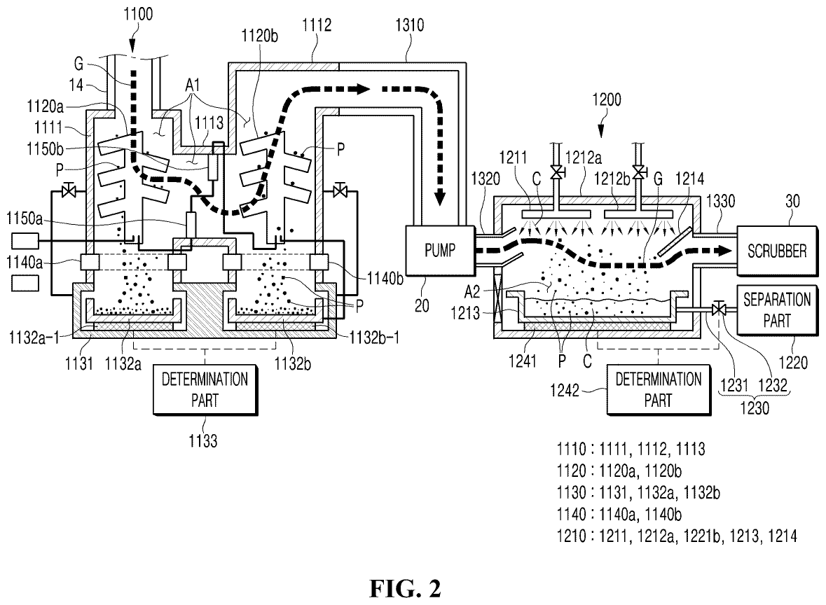

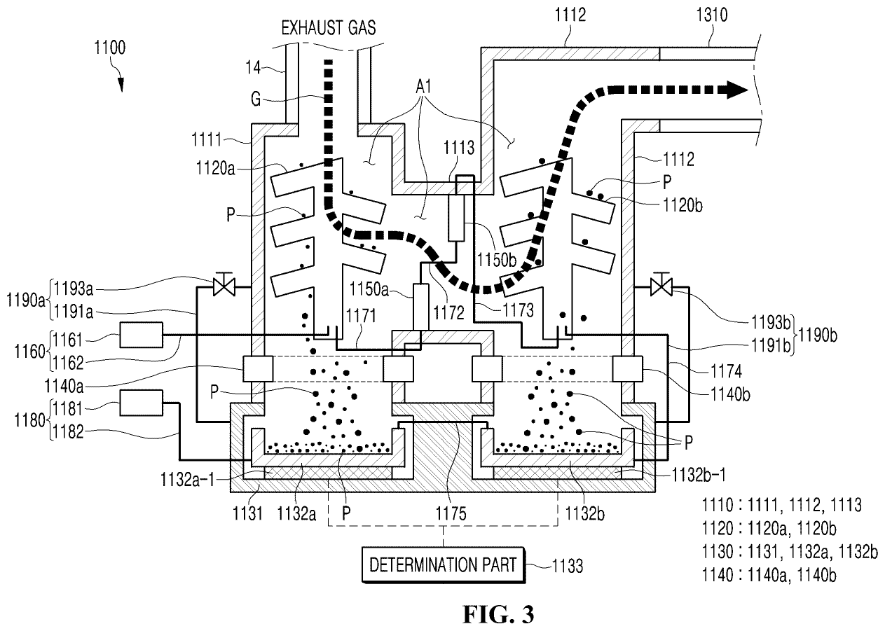

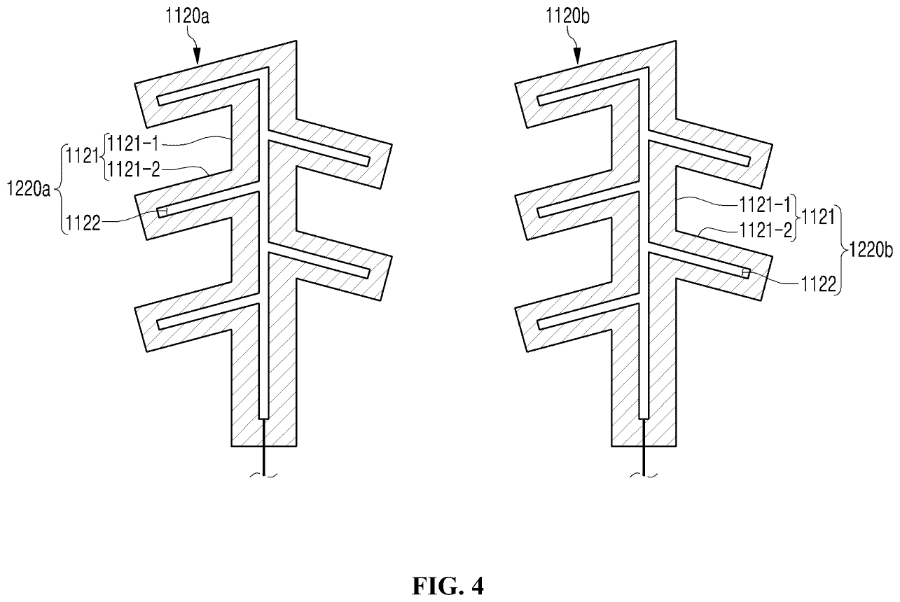

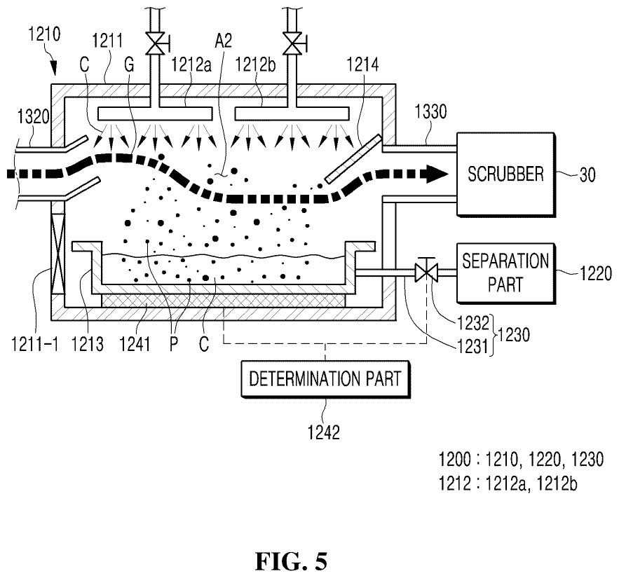

FIG. 2 is a view of the collecting device in accordance with an exemplary embodiment. FIG. 3 is a view illustrating a first collector of the collecting device in accordance with an exemplary embodiment. FIG. 4 is a view of a first cooling part, a second cooling part, a first partition wall, a second partition wall, and a a coolant transfer line connected to the first cooling part, the second cooling part, the first partition wall, and the second partition wall, 1 which are components through which a first coolant is circulated, in accordance with an exemplary embodiment. FIG. 5 is a view of a second collector in accordance with an exemplary embodiment.

Hereinafter, a collecting device in accordance with an exemplary embodiment will be described with reference to FIGS. 1 to 4.

Referring to FIG. 1, the collecting device 1000 includes is a first collector 1100 which is provided with a first passage A1, through which an exhaust gas discharged from the process device 10 passes, and a cooling part 1120 is installed inside the first passage A1 and provided with having a passage through which a first coolant passes. In addition, the collecting device 1000 may include a second collector 1200 which is provided with a second passage A2, through which an exhaust gas G transferred from the first collector 1100 passes, and an injection member that supplies a second coolant to the exhaust gas G passing through the inside of the second passage A2.

The first collector 1100 may be installed between an exhaust part 14 and a pump 20 of the process equipment 10, and the second collector 1200 may be installed or disposed at one side of the first collector 1100. As a more specific example, the second collector 1200 may be installed between the pump 20 and a scrubber 30 at one side of the first collector 1100. Thus, the collecting device 1000 may include a first transfer part 1310 connecting the first collector 1100 to the pump 20, a second transfer part 1320 connecting the pump 20 to the second collector 1200, and a third transfer part 1330 connecting the second collector 1200 to the scrubber 30.

The first collector 1100 cools the exhaust gas G discharged from the process device 10 to recover ruthenium contained in the exhaust gas G by transforming the exhaust gas G into solid particles or powder. As illustrated in FIGS. 2 and 3, the first collector 1100 includes a housing part 1110 having an internal space through which the exhaust gas G passes, a cooling part 1120 provided with a passage, through which a first coolant passes, and installed inside the housing part 1110 to cool the exhaust gas G passing through the inside of the housing part 1110, and an accommodation part 1130 connected to a lower portion of the housing part 1110 to accommodate ruthenium P that is in a state of powder generated by cooling the exhaust gas G. Here, the inside or internal space of the housing part 1110 is provided as the first passage A1.

In addition, the first collector 1100 may include an opening/closing part 1140 (1140a and 1140b) installed in the housing part 1110 to adjust communication between the housing part 1110 and the accommodation part 1130, a coolant supply part 1160 supplying the first coolant to the cooling part 1120, a coolant recovery part 1180 that recovers the first coolant passing through the cooling part 1120, and a pressure adjustment part 1190b (1190a and 1190b) that adjusts a pressure of the accommodation part 1130.

The housing part 1110 is a unit for allowing the exhaust gas G to pass and is provided with the first passage A1 through which a gas passes. The housing part 1110 is installed between the exhaust part 14 and the pump 20 of the process device 10 to connect the exhaust part 14 to the pump 20. That is, one end of the housing part 1110 is connected to the exhaust part 14 of the process device 10, and the other end is connected to the pump 20. In addition, one end of the housing part 1110 is opened to communicate with the exhaust part 14, and the other end is opened to communicate with the pump 20. Here, an opening provided at one end of the housing part 1110 is an inlet through which the exhaust gas G is introduced into the first passage A1, and an opening provided at the other end of the housing part 1110 is an outlet through which the exhaust gas of the first passage A1 is discharged to the outside.

The first passage A1 of the housing part 1110 may be bent two or more times rather than in a straight line. That is, the first passage A1 of the housing part 1110 is provided so that a path from the inlet to the outlet is not a straight line, but is bent several times. For this, the housing part 1110 may be constituted by a plurality of housings. For example, as illustrated in FIG. 3, the housing part 1110 may include a first housing 1111 connected to the exhaust part 14 of the process device 10, a second housing 1112 connected to the pump 20, and a connection housing 1113 connecting the first housing 1111 to the second housing 1112.

Each of the first housing 1111, the connection housing 1113, and the second housing 1112 is provided with a passage through which the exhaust gas G passes, and the first housing 1111, the connection housing 1113, and the second housing 1112 are connected to communicate with each other. Thus, the first passage A1 of the housing part 1110 may be described as including a passage of the first housing 1111, a passage of the connection housing 1113, and a passage of the second housing 1112. In addition, the exhaust gas discharged from the process device 10 is transferred to the second collector 1200 through the passage of the first housing 1111, the passage of the connection housing 1113, and the passage of the second housing 1112.

The first housing 1111, the connection housing 1113, and the second housing 1112 may be installed to be aligned in a horizontal direction. That is, the first housing 1111 and the second housing 1112 may be disposed to be spaced apart in the horizontal direction, and the connection housing 1113 may be installed between the first housing 1111 and the second housing 1112.

As described above, when the housing part 1110 is constituted by the first housing 1111, the connection housing 1113, and the second housing 1112, each of the cooling part 1120, the opening/closing part 1140 (1140a and 1140b), the pressure adjustment part 1190 (1190a and 1190b) may be provided in plurality. That is, the first collector 1100 may include a first cooling part 1120a installed inside the first housing 1111, a second cooling part 1120b installed inside the second housing 1112, a first opening/closing part 1140a installed in the first housing 1111 to control the communication between the first housing 1111 and the accommodation part 1130, a second opening/closing part 1140b installed in the second housing 1112 to control the communication between the second housing 1112 and the accommodation part 1130, and a second pressure adjustment part 1190b that adjusts a pressure of the accommodation part 1130 using a pressure of the second housing 1112.

In addition, the first collector 1100 may further include a plurality of partition walls 1150a and 1150b which is installed inside the connection housing 1113, and each of which is provided with a passage through which the first coolant flows.

Hereinafter, the first housing 1111, the connection housing 1113, and the second housing 1112 that constitute the housing part 1110 will be described in more detail.

The first housing 1111 is provided with a passage through which the exhaust gas G passes. In addition, the first housing 1111 is provided to communicate with the exhaust part 14, the connection housing 1113, and the accommodation part 1130 of the process device 10. For this, an opening may be provided in each of upper, lower, and side portions of the first housing 1111.

In addition, the upper opening of the first housing 1111 may communicate with the exhaust part 14, the lower opening may communicate with the accommodation part 1130, and the side opening may communicate with the connection housing 1113.

The connection housing 1113 is disposed between the first housing 1111 and the second housing 1112. Thus, the first housing 1111 and the second housing 1112 communicate with each other by the connection housing 1113.

The second housing 1112 is provided with a passage through which the exhaust gas G passes. In addition, the second housing 1112 is provided to communicate with the connection housing 1113, the accommodation part 1130, and the first transfer part 1310. For this, the openings may be provided in each of the side, upper, and lower portions of the second housing 1112. In addition, the side opening of the second housing 1112 communicates with the connection housing, the lower opening communicates with the accommodation part 1130, and the upper opening communicates with the first transfer part 1310.

Each of the first and second housings 1111 and 1112 may have a shape of which a length is longer in a vertical direction than a width (horizontal length) thereof, and the first housing 1111 and the second housing 1112 have the same width and length. In addition, the vertical length of the connection housing 1113 may be less than that of each of the first and second housings 1111 and 1112. In addition, the connection housing 1113 may be installed at a center of each of the first and second housings 1111 and 1112 based on the vertical direction.

As described above, as the housing part 1110 is constituted by the first housing 1111, the connection housing 1113, and the second housing 1112, the first passage A1 of the housing part 1110 may have a shape that is bent several times rather than a straight line. That is, the first passage A1, which provide a path from the upper opening (inlet) of the first housing 1111 to the upper opening (outlet) of the second housing 1112, is not provided in the straight but is provided in the shape that is bent several times.

In addition, a process through which the exhaust gas G passes through the first passage A1 of the housing 1110 is explained as follows. When the exhaust gas passes through the upper opening (inlet) of the first housing 1111, the exhaust gas G is introduced into the first housing 1111 and is then transferred to the connection housing 1113. In addition, the exhaust gas transferred to the connection housing 1113 is introduced into the second housing 1112 and is then discharged through the upper opening (outlet) of the second housing 1112. While the exhaust gas G flows by sequentially passing through the first housing 1111, the connection housing 1113, and the second housing 1112, the exhaust gas G is cooled. Here, the exhaust gas G is cooled by the cooling part described later, and as a result, ruthenium of components contained in the exhaust gas G is cooled and powdered. That is, ruthenium is recovered from the exhaust gas G. Then, the recovered ruthenium P passes through the lower openings of the first and second housings 1111 and 1112 and is then collected into the accommodation part 1130 disposed below.

As described above, if the first passage A1 of the housing part 1110 is provided in a shape that is bent several times, a time for which the exhaust gas remains in the first passage A1 may extend. That is, the residence time, which is a time before the exhaust gas G introduced into the first passage A1 of the housing 1110 is discharged to the outside of the housing 1110, may extend. As a result, ruthenium contained in the exhaust gas G may be sufficiently cooled to improve collection efficiency of ruthenium P.

In addition, the first collector 1100 is connected between the process device 10 and the pump 20 as illustrated in FIG. 1. In addition, the inside of the chamber 11 of the process device 10 may be adjusted to a vacuum pressure by an operation of the pump 20. That is, when performing a substrate processing process in the process device 10, the inside of the chamber 11 may be adjusted to the vacuum pressure. Here, the first collector 1100 is connected between the chamber 11 and the pump 20. That is, the housing part 1110 is connected between the chamber 11 and the pump 20. Thus, the first collector 1100 may be in a vacuum state. That is, the housing part 1110 may be in a vacuum state. In more detail, when performing the substrate processing process in the process device 10, the pressure of the chamber 11 may be a vacuum pressure, and thus, the housing part 1110 may be adjusted to the vacuum state.

The first cooling part 1120a is installed inside the first housing 1111 to cool the exhaust gas G passing through the inside of the first housing 1111. The first cooling part 1120a includes a body 1121 and a passage 1122 provided inside the body 1121 to allow the first coolant to pass therethrough.

The body 1121 may include a first body 1121-1 extending in a vertical direction and a plurality of second bodies 1121-2 spaced apart from an outer surface of the first body 1121-1 in the vertical direction.

The first body 1121-1 may be provided in a cylindrical shape extending in the vertical direction. A shape of the first body 1121-1 is not limited to the above-described example, and the first body 1121-1 may extend in a direction, in which the first housing 1111 extends, and be provided in various shapes in which a plurality of second bodies 1121-2 are mounted to be spaced apart from each other.

The second body 1121-2 may have a plate shape extending in a direction intersecting the extension direction of the first body 1121-1. For example, the second body 1121-2 may have a plate shape extending in a circumferential direction of the first body 1121-1. In addition, the second body 1121-2 may be connected to an outer surface of the first body 1121-1. In addition, the second body 1121-2 may be inclined so that a height thereof decreases as it moves away from the first body 1121-1. To explain this in more detail, an end of the second body 1121-2 connected to the outer surface of the first body 1121-1 is called one end, and the other end opposite to the one end of the second body 1121-2 is called the other end. To reflect this and explain again, the second body 1121-2 is installed to be inclined so that the other end thereof has a height less than that of the one end thereof. That is, the second body 1121-2 is installed to be inclined so that the height thereof decreases from one end to the other end. In other words, the second body 1121-2 is installed so that the first body 1121-1 and the second body 1121-2 have a predetermined angle rather than vertical (90°) therebetween.

The second body 1121-2 is provided in plurality, each of which is installed on the first body 1121-1. Here, the plurality of second bodies 1121-2 are installed to be spaced apart from each other in the vertical direction. In addition, the plurality of second bodies 1121-2 disposed adjacent to each other in the vertical direction are disposed to be misaligned so that their horizontal positions are different. For example, two second bodies 1121-2 disposed adjacent to each other in the vertical direction may be installed to face each other with the first body 1121-1 therebetween.

As illustrated in FIG. 4, a passage 1122 through which the first coolant passes is provided inside the body 1121 as described above. Here, the passage 1122 may be provided to extend entirely through the inside of the body 1121. In other words, the passage 1122 is provided to extend along a shape of the body. That is, the passage 1122 is provided inside each of the first body 1121-1 and the plurality of second bodies 1121-2 of the body 1121, and the passages 1122 provided in the first body 1121-1 and the plurality of second bodies 1121-2 are connected to communicate with each other. One end of the passage 1122 extending as described above may be connected to the coolant supply part 1160, and the other end may be connected to a first coolant transfer line 1171, which will be described later. Here, each of one end of the passage 1122 connected to the coolant supply part 1160 and the other end of the passage 1122 connected to the first coolant transfer line 1171 may be disposed at a lower portion inside the first body 1121-1 as illustrated in FIG. 4.

The coolant supply part 1160 supplies the first coolant to the passage 1122 of the first cooling part 1120a. That is, the first coolant is supplied to the passage 1122 provided in the body 1121. When the first coolant is supplied to the passage 1122 provided inside the body 1121, the first coolant moves inside the body 1121 along the passage 1122. Thus, the first cooling part 1120a is cooled. In addition, the first coolant discharged from the first cooling part 1120a is supplied to the passage 1122 of the second cooling part 1120b, which will be described later, and thus, the second cooling part 1120b is cooled.

As described above, the coolant supply part 1160 supplies the first coolant to the first and second cooling parts 1120a and 1120b to cool the first and second cooling parts 1120a and 1120b. Here, the first and second cooling parts 1120a and 1120b need to cool the ruthenium contained in the exhaust gas G to a temperature at which ruthenium is powdered or recovered. That is, the first and second cooling parts 1120a and 1120b may be cooled to a temperature of approximately 10° C. or less to recover ruthenium contained in the exhaust gas G. For this, the first coolant may be adjusted to a temperature at which ruthenium is recovered. That is, the first coolant may have a temperature of approximately 10° C. or less.

When the exhaust gas G is introduced into the first housing 1111, the introduced exhaust gas G is cooled by the first cooling part 1120a. That is, the exhaust gas G passing to be in contact with an outer circumferential surface of the first cooling part 1120a or the exhaust gas G passing around the first cooling part 1120a is cooled to a temperature of approximately 10° C. or less. Here, the exhaust gas G contains ruthenium that is a component that becomes solid or powder at a temperature of approximately 10° C. or less. Thus, when the exhaust gas G is cooled to a temperature of approximately 10° C. or less, ruthenium powder is generated. That is, ruthenium is recovered from the exhaust gas G.

In addition, as described above, the plurality of second bodies 1121-2 of the first cooling part 1120a are disposed to be spaced apart from each other in the vertical direction, and the two second bodies 1121-2 disposed adjacent to each other in the vertical direction are disposed to be misaligned in the horizontal direction. As a result, a time for which the exhaust gas remains inside the first housing 1111 may extend, and the exhaust gas passing through the inside of the first housing 1111 may be uniformly cooled. Thus, ruthenium contained in the exhaust gas G may be sufficiently cooled, and the collection efficiency of ruthenium may be improved.

In addition, the second body 1121-2 is inclined so that a height thereof decreases as it moves away from the first body 1121-1. Thus, the recovered ruthenium P may easily move downward along an inclination of the second body 1121-2.

The second cooling part 1120b is installed inside the second housing 1112 to serve as a unit that cools the exhaust gas G passing through the inside of the second housing 1112. This second cooling part 1120b may be provided with the same configuration and shape as the first cooling part 1120a, except that the installation positions are different from each other. That is, the second cooling part 1120b includes the body 1121 installed inside the second housing 1112 and the passage 1122 provided inside the body 1121 to allow the first coolant to pass therethrough. In addition, the body 1121 may include a first body 1121-1 extending in a vertical direction and a plurality of second bodies 1121-2 spaced apart from an outer surface of the first body 1121-1 in the vertical direction. In the passage provided inside the body 1121 of the second cooling part 1120b, the first coolant is introduced into one end, and the first coolant is discharged from the other end. Here, the first body 1121-1 and the second body 1121-2 of the second cooling part 1120b are the same as the first body 1121-1 and the second body 1121-2 of the second cooling part 1120b. Thus, descriptions of the first body 1121-1 and the second body 1121-2 of the second cooling part 1120b will be omitted.

A process in which the exhaust gas G is cooled by the second cooling part 1120b, and ruthenium contained in the exhaust gas G is powdered or recovered is the same as the process described in the first cooling part 1120a. This is briefly explained below.

The exhaust gas G containing ruthenium that is not recovered while passing through the first housing 1111 may be introduced into the second housing 1112. Here, the exhaust gas G introduced into the second housing 1112 is cooled by the second cooling part 1120b. That is, the exhaust gas G passing to be in contact with an outer circumferential surface of the second cooling part 1120b or the exhaust gas G passing around the second cooling part 1120b is cooled. Thus, ruthenium is recovered from the exhaust gas G, and the recovered ruthenium P is collected into the accommodation part 1130.

The connection housing 1113 is installed between the first housing 1111 and the second housing 1112. Thus, the exhaust gas introduced into the first housing 1111 moves to the second housing 1112 through the connection housing 1113. A plurality of partition walls 1150a and 1150b are installed inside this connection housing 1113. For example, as illustrated in FIG. 3, two partition walls (hereinafter, referred to as first and second partition walls 1150a and 1150b) may be installed inside the connection housing. In addition, a passage 1151 through which the first coolant passes may be provided inside the first and second partition walls 1150a and 1150b. As a result, the first and second partition walls 1150a and 1150b may be cooled. Thus, the exhaust gas G discharged from the first housing 1111 may be cooled by the first and second partition walls 1150a and 1150b while passing through the connection housing. Here, the first and second partition walls 1150a and 1150b may be cooled to a temperature at which ruthenium contained in the exhaust gas G is cooled. That is, the first and second partition walls 1150a and 1150b may be cooled to a temperature of approximately 10° C. or less. Thus, the exhaust gas G passing through the inside of the connection housing 1113 may be cooled to a temperature of approximately 10° C. or less by the first and second partition walls 1150a and 1150b. As a result, ruthenium contained in the exhaust gas G may be recovered.

The first partition wall 1150a and the second partition wall 1150b are installed at different positions within the connection housing 1113. For example, the first partition wall 1150a and the second partition wall 1150b may be disposed in the direction in which the first housing 1111 and the second housing 1112 are arranged, that is, in the horizontal direction. Thus, the first partition wall 1150a and the second partition wall 1150b may be installed at different heights. For example, in the first and second partition walls 1150a and 1150b, the first partition wall 1150a, which is disposed relatively adjacent to the first housing 1111, may be disposed lower than the second partition wall 1150b. To explain this in other words, in the first and second partition walls 1150a and 1150b, the second partition wall 1150b, which is disposed relatively adjacent to the second housing 1112, is disposed above the first partition wall 1150a. As a result, when installing the plurality of partition walls 1150a and 1150b inside the connection housing 1113, a moving path of the exhaust gas G passing through the connection housing 1113 may extend by being installed at different positions. Thus, a time for which the exhaust gas G remains inside the connection housing 1113 may extend, and thus, the exhaust gas G may be sufficiently cooled. Thus, the collection efficiency of ruthenium contained in the exhaust gas G may be improved.

In the above, it has been described that the temperatures of the first and second cooling parts 1120a and 1120b and the first and second partition walls 1150a and 1150b are adjusted to a temperature of approximately 10° C. or less. However, the temperatures of the first and second cooling parts 1120a and 1120b and the first and second partition walls 1150a and 1150b are not limited to the above-described examples, and if ruthenium is powdered to be recovered, the first and second cooling parts 1120a and 1120b and the first and second partition walls 1150a and 1150b may be adjusted to a certain temperature.

In addition, as described above, the first collector 1100 includes a housing part 1110 that has a space through which the exhaust gas G passes. Thus, the first collector 1100 may be described as including the space through which the exhaust gas G passes. In addition, the housing part includes a first housing 1111, a connection housing 1113, and a second housing 1112, and each of the first housing 1111, the connection housing 1113, and the second housing 1112 is provided with a passage, i.e., a space through which the exhaust gas G passes. Here, the space provided in the first housing 1111 may be referred to as a first space, the space provided in the second housing 1112 may be referred to as a second space, and the space provided in the connection housing 1113 may be referred to as a third space. Thus, the first collector 1100 may be described as including a space through which the exhaust gas G passes and cooling parts 1120a and 1120b installed in the space. In more detail, the first collector 1100 may be described as including the first space, the second space, the third space defined between the first space and the second space, and the first and second cooling parts 1120a and 1120b respectively installed in the first and second spaces.

The accommodation part 1130 accommodates the recovered ruthenium (Ru) and is connected to a lower portion of the housing part 1110. The accommodation part 1130 may include a body 1131 connected to the lower portion of the housing part 1110 and first and second containers 1132a and 1132b, each of which has an internal space that accommodates the ruthenium P and installed in the body 1131.

The body 1131 may have an internal space and may have a shape with an opening at an upper portion facing the housing part 1110. In addition, the body 1131 may have a shape extending in the direction in which the housing part 1110 extends. That is, the body 1131 may have a shape extending in the direction in which the first housing 1111, the connection housing 1113, and the second housing 1112 are arranged. In addition, an opening is provided in the upper portion of the body 1131 to communicate with the first and second housings 1111 and 1112. That is, a first opening is provided at a position facing the lower opening of the first housing 1111 in the upper portion of the body 1131, and a second opening is provided at a position facing the lower opening of the second housing 1112. Thus, the ruthenium P passing through the lower openings of the first and second housings 1111 and 1112 may pass through the first and second openings provided in the upper portion of the body 1131 and then be introduced into the body 1131.

Each of the first and second containers 1132a and 1132b is installed inside the body 1131. Here, the first container 1132a is installed at a position facing the first housing 1111 inside the body 1131, and the second container 1132b is installed at a position facing the second housing 1112 inside the body 1131.

Each of the first and second containers 1132a and 1132b may have a shape with an opening in an upper portion thereof. Thus, the ruthenium P passing through the first and second openings of the body 1131 may be introduced into the first and second containers 1132a and 1132b.

A passage through which the first coolant is circulated is provided in each of the first and second containers 1132a and 1132b. That is, a passage may be provided inside the walls constituting the first and second containers 1132a and 1132b. As a result, the first and second containers 1132a and 1132b may be cooled by the first coolant. Thus, ruthenium (Ru) contained in the first and second containers 1132a and 1132b may be prevented from increase in temperature and being gasified again.

The ruthenium P recovered from the exhaust gas G may be accommodated in the first and second containers 1132a and 1132b. In addition, if more than a certain amount of ruthenium P is accommodated inside the first and second containers 1132a and 1132b, each of the first and second containers 1132a and 1132b have to be replaced with a new container. Here, since the first and second containers 1132a and 1132b are installed inside the body 1131, the first and second containers 1132a and 1132b have to be carried out from the body 1131. For this, the body 1131 is provided so as to be coupled to and separated from the housing part 1110. That is, the body 1131 is provided so as to be coupled to or separated from the first and second housings 1111 and 1112 and the connection housing 1113. Here, a unit that couples the body 1131 and the housing part 1110 to each other is not particularly limited.

In the above, it has been explained that, in order to carry out the first and second containers 1132a and 1132b out of the body 1131, the body 1131 is provided in a structure that is capable of being separated from the housing part 1110. However, it is not limited thereto, and a gate (not shown) through which the first and second containers 1132a and 1132b are carried in and out, respectively, may be provided in the body 1131. For example, a first gate (not shown) is provided in one surface of the body 1131 to allow the first container 1132a to be carried in and out, and a second gate (not shown) may be provided in the other surface of the body 1131 to allow the second container 1132b to be carried in and out.

To determine whether the first and second containers 1132a and 1132b need to be replaced, it is desirable to measure an amount of ruthenium P contained in each of the first and second containers 1132a and 1132b. For this, the first collector 1100 may include a measurement part that detects the ruthenium P contained in each of the first and second containers 1132a and 1132b and a determination part 1133 that determines whether replacement of each of the first and second containers is required using a value (hereinafter, referred to as a measured value) measured in the measurement part.

The measurement part includes a first measurement part 1132a-1 capable of detecting the ruthenium P inside the first container 1132a and a second measurement part 1132b-1 capable of detecting the ruthenium P inside the second container 1132b, which are provided separately. Here, the first and second measurement parts 1132a-1 and 1132b-1 may be, for example, units for respectively measuring amounts of ruthenium P inside the first and second containers. In addition, each of the first and second measurement parts 1132a-1 and 1132b-1 is a weight measurement part that measures a weight of each of the containers 1132a and 1132b or a height sensor that measures a height of the ruthenium P accumulated in each of the containers 1132a and 1132b. Here, the height of the ruthenium P accommodated and accumulated inside each of the containers 1132a and 1132b may mean a height of a top surface of a layer having a predetermined thickness due to the accumulation of the ruthenium P that is in a powder state. Thus, the height of the ruthenium P accumulated inside the containers 1132a and 1132b may mean a ‘height of the ruthenium Player.’

In addition, the determination part 1133 determines whether each of the first and second containers 1132a and 1132b needs to be replaced by comparing the measured amount of ruthenium P with a preset reference value. Here, when the first and second measurement parts 1132a-1 and 1132b-1 are the weight measurement parts, the reference value set in the determination part 1133 may be a reference weight. As another example, when the first and second measurement parts 1132a-1 and 1132b-1 are the height sensors, the reference value set in the determination part 1133 may be a reference height.

Hereinafter, a process for determining whether the first and second containers 1132a and 1132b need to be replaced using the first and second measurement parts 1132a-1 and 1132b-1 and the determination part 1133 will be described. Here, the case in which the first and second measurement parts 1132a-1 and 1132b-1 are the weight measurement parts will be described as an example. Thus, the first measurement part 1132a-1 may be referred to as a first weight measurement part, and the second measurement part 1132b-1 may be referred to as a second weight measurement part. In addition, for convenience of explanation, the reference numeral of the first weight measurement part will be referred to as the same as that of the first measurement part 1132a-1, and the reference numeral of the second weight measurement part will be referred to as the same as that of the second measurement part 1132b-1.

The determination part 1133 receives the weight measured in real time from the first and second weight measurement parts 1132a-1 and 1132b-1 and compares the transmitted measured weight with a preset reference weight. In addition, the determination part 1133 generates an alarm that notifies the replacement of the first and second containers 1132a and 1132b when the measured weight exceeds the reference weight. Here, the determination part 1133 receives the weight of the first container 1132a measured by the first weight measurement part 1132a-1 and the weight of the second container 1132b measured by the second weight measurement part 1132b-1. In addition, the determination part 1133 compares each of the weight of the first container 1132a and the weight of the second container 1132b with the reference weight to determine whether each of the first and second containers 1132a and 1132b needs to be replaced. Here, if it is determined that at least one of the first and second containers 1132a and 1132b needs to be replaced, the determination part 1133 generates a replacement alarm. In addition, the determination part 1133 may classify and notify that any container of the first and second containers 1132a and 1132b needs to be replaced.

In the above, the case in which the first and second measurement parts 1132a-1 and 1132b-1 are the weight measurement parts was described as an example. However, it is not limited thereto, and the first and second measurement parts may be the height sensors. In this case, a light-transmitting window (not shown) may be provided in each of the body 1131 and the first and second containers 1132a and 1132b. In more detail, the window may be provided in each of the first container 1132a and the second container 1132b. In addition, in the body 1131, a first window may be provided at a position facing the window of the first container 1132a, and a second window may be provided at a position facing the window of the second container 1132b. In addition, the first and second height sensors that measure the height by irradiating light may be installed outside the body. Here, the first height sensor may be installed at a position facing the first window of the body 1131, and the second height sensor may be installed at a position facing the second window of the body 1131.

Light emitted from each of the first and second height sensors may pass through the first and second windows of the body 1131 and the windows provided in the first and second containers 1132a and 1132b and then be irradiated into the first and second containers 1132a and 1132b. In addition, the height of the ruthenium P contained in each of the first and second containers 1132a and 1132b may be measured using the light irradiated into the first and second containers 1132a and 1132b. The height of the ruthenium P in the first and second containers 1132a and 1132b measured by the first and second height sensors may be transmitted to the determination part 1133. In addition, the determination part 1133 compares the height of the ruthenium P measured by each of the first and second height sensors with the preset reference height. In addition, the determination part 1133 generates an alarm that notifies the replacement of the first and second containers 1132a and 1132b when the measured height of ruthenium P exceeds the reference height.

Here, the determination part 1133 receives the height of the ruthenium P in the first container 1132a measured by the first height sensor and the height of the ruthenium P in the second container 1132b measured by the second height sensor. In addition, the determination part 1133 compares the height of the ruthenium P in the first container 1132a and the height of the ruthenium P in the second container 1132b with the reference height to determine whether the first and second containers 1132a are 1132b need to be replaced. Here, if it is determined that at least one of the first and second containers 1132a and 1132b needs to be replaced, the determination part 1133 generates a replacement alarm. In addition, the determination part 1133 may classify and notify that any container of the first and second containers 1132a and 1132b needs to be replaced.

In the above, it has been explained that the height of the ruthenium P is measured by irradiating the light through the body 1131, i.e., the window. However, it is not limited thereto, and an operator directly checks the height of the ruthenium P through the windows provided in the body 1131 and the first and second containers 1132a and 1132b to directly determine whether the first and second containers 1132a and 1132b need to be replaced using the checked height.

In addition, in the above description, an example is given in which the measurement part is the weight measurement part that measures the weight of the container or the height sensor that measures the height of the ruthenium P. However, the measurement part is not limited thereto and may be a unit of measuring something other than weight and height.

A specific method of replacing the first and second containers 1132a and 1132b will be described later after explaining the first and second opening/closing parts 1140a and 1140b and the first and second pressure adjustment parts 1190a and 1190b.

The first opening/closing part 1140a is a unit for the opening and closing between the first housing 1111 and the accommodation part 1130, and is installed in the first housing 1111. Here, the first opening/closing part 1140a is installed in the first housing 1111 to be disposed between the first cooling part 1120a and the accommodation part 1130. In addition, the second opening/closing part 1140b is a unit for the opening and closing between the second housing 1112 and the accommodation part 1130, and the second opening/closing part 1140b is installed in the second housing 1112 so as to be disposed between the second cooling part 1120b and the accommodation part 1130.

The first and second opening/closing parts 1140a and 1140b may be maintained in an opened state when the first and second containers 1132a and 1132b are not replaced and then be closed when the first and second containers 1132a and 1132b are replaced. More specifically, while the process device 10 operates to maintain the opened state of the first and second opening/closing parts 1140a and 1140b of the collecting device 100 while depositing the thin film on the substrate S. Thus, the first and second housings 1111 and 1112 of the housing part 1110 and the accommodation part 1130 communicate with each other. Thus, the ruthenium P that is in a powder state, which is generated by cooling the exhaust gas G inside the housing part 1110 may be collected in the accommodation part 1130.

The coolant supply part 1160 is a unit for supplying the first coolant to the first cooling part 1120a. The coolant supply part 1160 may include a coolant storage tank 1161 in which the first coolant is stored and a coolant supply line 1162 connecting the coolant storage tank 1161 to the passage 1122 of the first cooling part 1120a. Here, the first coolant stored in the coolant storage tank 1161 may be liquid or gas and may be adjusted to a temperature of approximately 10° C. or less. The coolant supply line 1162 is a pipe through which the first coolant passes or is transferred. Here, one end of the coolant supply line 1162 is connected to the coolant storage tank 1161, and the other end is connected to the passage of the first cooling part 1120a. More specifically, the other end of the coolant supply line 1162 is connected to one end of the passage 1122 of the first cooling part 1120a.

In addition, coolant transfer lines 1171 to 1173 are installed between the first cooling part 1120a and the first partition wall 1150a, between the first partition wall 1150a and the second partition wall 1150b, and between the second partition wall 1150b and the second cooling part 1120b. That is, the first collector 1100 may include a first coolant transfer line 1171 connecting the other end of the passage 1122 of the first cooling part 1120a to one end of the passage provided in the first partition 1150a, a second coolant transfer line 1172 connecting the other end of the passage provided in the first partition 1150a to one end of the passage provided in the second partition wall 1150b, and a third coolant transfer line 1173 connecting the other end of the passage provided in the second partition wall 1150b to one end of the passage 1122 of the second cooling part 1120b. Thus, the first coolant discharged from the passage 1122 of the first cooling part 1120a is transferred to the passage 1122 of the second cooling part 1120b through the first coolant transfer line 1171, the passage of the first partition 1150a, the second coolant transfer line 1172, the passage of the second partition 1150b, and the third coolant transfer line 1173.

In addition, a fourth coolant transfer line 1174 is installed between the passage 1122 of the second cooling part 1120b and the passage of the second container 1132b, and a fifth coolant transfer line 1175 is installed between the passage of the second container 1132b and the passage of the first container 1132a. Thus, the first coolant discharged from the passage 1122 of the second cooling part 1120b may be transferred to the passage of the first container 1132a through the fourth coolant transfer line 1174, the passage of the second container 1132b, and the fifth coolant transfer line 1175.

The coolant recovery part 1180 is a unit that recovers the first coolant discharged from the passage of the second container 1132b. The coolant recovery part 1180 may include a coolant recovery line 1182 connected to the other end of the passage of the second container 1132b and a coolant recovery tank 1181 that accommodates the first coolant transferred from the coolant recovery line 1182. Thus, the first coolant discharged from the passage of the second container 1132b may be stored in the coolant recovery tank through the coolant recovery line 1182.

The first pressure adjustment part 1190a adjusts a pressure of the accommodation part 1130 using the pressure of the first housing 1111. The first pressure adjustment part 1190a includes a first line 1191a installed to connect the first housing 1111 to the body 1131. In addition, the first pressure adjustment part 1190a may further include a first valve 1193a installed in the first line 1191a so that the first housing 1111 and the body 1131 communicate with each other, a second line (not shown) connected to the first line 1191a, and a second valve (not shown) connected to an end of the second line (not shown).

The second pressure adjustment part 1190b has the same configuration as the above-described first pressure adjustment part 1190a, except for an installation position. That is, the second pressure adjustment part 1190b may include a first line 1191b installed to connect the second housing 1112 to the body 1131 and a first valve 1193b installed in the first line 1191b so that the second housing 1112 and the body 1131 communicate with each other. In addition, the second pressure adjustment part 1190b may include a second line (not shown) connected to the first line 1191b and a second valve (not shown) connected to an end of the second line (not shown).

As described above, the adjusting of the pressure of the accommodation part 1130 using the first and second pressure adjustment parts 1190a and 1190b may be performed after replacing at least one of the first and second containers 1132a and 1132b.

Hereinafter, after the determination part 1133 determines that replacement of the first container 1132a is necessary, a method for replacing the first container 1132a and a method for adjusting the pressure of the accommodation part 1130 after replacing the first container 1132a will be described.

First, the first and second opening/closing part 1140a and 1140b are closed. In addition, the body 1131 of the accommodation part 1130 is separated from the housing part 1110. Next, in the first and second containers 1132a and 1132b loaded inside the body 1131, the first container 1132a that needs to be replaced is carried out of the body. Next, a new first container 1132a having an empty therein is loaded into the body. Next, the body 1131 is coupled to the housing part 1110.

In the process of replacing the first container 1132a, the inside of the body is exposed to the atmosphere. Thus, the inside of the body 1131 may currently be at an atmospheric pressure. Thus, when the body 1131 is coupled to the housing part 1110, the pressure of the body 1131 is lowered. For this, the first valves 1193a and 1193b of the first and second pressure adjustment parts 1190a and 1190b are opened to communicate with the first and second housings 1111 and 1112 and the body 1131. Thus, the pressure of the body 1131 may decrease and thus may become the same as the pressure of the housing part 1110. In addition, when the pressure of the body 1131 is the same as or close to the pressure of the housing, the first and second opening/closing parts 1140a and 1140b are opened.

Hereinafter, the second collector will be described with reference to FIGS. 1, 2, and 5.

The second collector 1200 cools the exhaust gas G transferred from the first collector 1100 to cool ruthenium contained in the exhaust gas G, thereby collecting ruthenium that is in a powder state. That is, the second collector 1200 cools the exhaust gas G transferred from the first collector 1100 to recover ruthenium from the exhaust gas G. The second collector 1200 may be installed between the pump 20 and the scrubber 30.

Referring to FIGS. 2 and 5, the second collector 1200 includes a wet cooling part 1210 that injects a second coolant C to the exhaust gas transferred from the first collector 1100 to cool the exhaust gas and a separation part that receives a mixture of the coolant C and the ruthenium P from the wet cooling part 1210 and separates the second coolant C and the ruthenium P from the mixture. In addition, the second collector 1200 may include a transfer part 1230 that transfers the mixture in the wet cooling part 1210 to the separation part 1220.

The wet cooling part 1210 may include a body 1211 having an internal space, injection members 1212 (1212a and 1212b) installed in the body 1211 to inject the second coolant C into the body 1211, a container 1213 installed below the injection member 1212 (1212a and 1212b) inside the body 1211. In addition, the wet cooling part 1210 may include a blocking member 1214 installed inside the body 1211 to block the second coolant C inside the body 1211 from being introduced into the scrubber 30.

The body 1211 has a cylindrical shape having an internal space and is installed between the pump 20 and the scrubber 30. More specifically, the body 1211 is installed between the second transfer part 1320 connected to the pump 20 and the third transfer part 1330 connected to the scrubber 30. In addition, the second transfer part 1320 and the third transfer part 1330 are connected to the body 1211, and an opening is provided in a portion at which the second and third transfer parts 1310 and 1320 are connected to each other. That is, the openings are provided on one side and the other side of the body 1211, respectively. In addition, the opening provided at one side of the body 1211 communicates with the second transfer part 1320, and the opening provided at the other side of the body 1211 communicates with the third transfer part 1330. Here, the opening provided at one side of the body 1211 is an inlet that allows the exhaust gas provided from the second transfer part 1320 to be introduced into the body 1211, and the opening provided at the other side of the body 1211 is an outlet that allow the exhaust gas inside the body 1211 to be discharged to the third transfer part. The internal space of the body 1211 becomes a second passage A2 of the collecting device 1000.

The body 1211 is provided with a gate G for carrying in and out of the container 1213. For example, a gate 1211-1 may be provided at one side of the body 1211. The gate 1211-1 may be provided at any position in the body 1211 as long as it allows the container 1213 to be carried out and in.

The injection members 1212 (1212a and 1212b) are installed in the body 1211 to inject the second coolant into the body 1211, that is, into the second passage A2. Here, the second coolant injected into the body 1211 through the injection members 1212 (1212a and 1212b) may be adjusted to a temperature at which the gaseous ruthenium is cooled to be powdered. The second coolant may be a liquid, for example, water. The second coolant C is not limited to water, and various liquid materials that are capable of cooling ruthenium contained in the exhaust gas G to be solidified or powdered may be used.

The plurality of injection members 1212 (1212a and 1212b) may be provided, and as illustrated in FIG. 5, for example, two injection members (1212a and 1212b) may be provided. The first and second injection members 1212a and 1212b may be installed in a direction in which the second transfer part 1320 and the third transfer part 1330 are arranged.

In the above, it has been described that the two injection members are provided, but the present disclosure is not limited thereto, and the number of injection members may be more than two. In addition, the injection member may be provided as one rather than in plurality.

When the exhaust gas is introduced into the body 1211, and the second coolant C is injected from the first and second injection members 1212a and 1212b, the exhaust gas G is cooled by the injected second coolant C. Here, ruthenium contained in the exhaust gas G is cooled to be powdered. That is, the ruthenium P is recovered from the exhaust gas G. In addition, the recovered ruthenium P and the second coolant C injected from the injection members 1212 (1212a and 1212b) fall downward.

Hereinafter, to distinguish the container from the first and second containers 1132a and 1132b of the first collector 1100, the container 1213 installed inside the body 1211 of the second collector 1200 is referred to as a ‘third container 1213’.

The third container 1213 is installed inside the body 1211 to face the injection members 1212 1212a and 1212b. In addition, the third container 1213 is provided in a shape that is capable of receiving and accommodating the recovered ruthenium P and the second coolant C. That is, the third container 1213 may have an internal space and have an opened upper portion facing the injection members 1212a and 1212b.

The third container 1213 accommodates the ruthenium P and the second coolant C as described above. That is, the ruthenium P and the second coolant C are mixed to be accommodated inside the third container 1213. Here, the recovered ruthenium P that is in the form of solid or powder is a metal having a specific gravity greater than that of the second coolant C. Thus, when the mixture is received in the third container, the ruthenium (Ru) may be precipitated in the second coolant. In addition, the mixture is discharged to the separation part 1220 through the transfer part 1230. For this, an opening communicating with the transfer part 1230 is provided in the third container 1213.

The blocking member 1214 serves to block or shield the second coolant C injected into the body 1211 from being introduced into the scrubber 30. To be more specific, the blocking member 1214 blocks the second coolant C injected into the body 1211 from being discharged through the outlet and introduced into the third transfer part 1330.

The blocking member 1214 is installed inside the body 1211 to face the outlet. Here, the blocking member 1214 may be installed between the injection members 1212a and 1212b and the outlet. Here, when the wet cooling part 1210 includes a plurality of injection members 1212a and 1212b, the blocking member 1214 may be disposed between the injection member disposed closest to the outlet and the outlet. More specifically, as illustrated in FIG. 5, when the wet cooling part 1210 includes the first and second injection members 1212a and 1212b, the blocking member 1214 is disposed between the second injection member 1212b and the outlet. In addition, the blocking member 1214 is installed at an angle so that a height thereof decreases from the outlet toward the second injection member 1212b. Thus, the blocking member 1214 has one surface facing the outlet and does not close the outlet. Thus, the second coolant C injected from the injection members 1212a and 1212b may not be introduced into the outlet because its movement is blocked by the blocking member 1214, and the exhaust gas G may be introduced into a space between the blocking member 1214 and the outlet and then be discharged through the outlet.

The separation part 1220 separates the ruthenium P from the mixture discharged from the third container 1213. That is, the separation part 1220 separates the ruthenium P precipitated in the second coolant C. In other words, the liquid second coolant C is dehydrated from the mixture to separate the powdered ruthenium P. The separation part 1220 may, for example, be a unit of providing a filter that allows the second coolant C to pass therethrough, but does not allow the ruthenium P to pass therethrough.

The transfer part 1230 includes a transfer pipe 1231 connecting the third container 1213 to the separation part 1220, and a valve 1232 installed in the transfer pipe to control communication between the third container 1213 and the separation part 1220.

The valve 1232 of the transfer part 1230 may operate so that the opened state is maintained while the wet cooling part 1210 operates. Thus, while the wet cooling part 1210 operates, a mixture in the third container 1213 may be discharged to the separation part 1220 through the transfer part 1230.

The valve of the transfer part is not limited thereto and may be selectively opened and closed depending on an amount of mixture contained in the third container.

For this, the second collector 1200 may include a measurement part 1241 capable of detecting the mixture contained in the third container 1213 and a determination part 1242 that adjusts an opening and closing of the valve 1232 depending on a value (hereinafter, referred to as a measured value) measured in the measurement part 1241.

Here, the measurement part 1241 may be a unit for measuring an amount of mixture contained in the third container 1213. As a more specific example, the measurement part 1241 may be a weight measurement part that measures a weight of the third container 1213, or a height sensor that measures a height of the mixture contained inside the third container 1213.

In addition, the determination part 1242 controls an operation of the valve 1232 by comparing the measured amount of mixture with a preset reference value. Here, when the measurement part 1241 is the weight measurement part, the reference value set in the determination part 1242 may be a reference weight. As another example, when the measurement part 1241 is the height sensor, the reference value set in the determination part 1242 may be a reference height.

Hereinafter, a method for controlling the operation of the valve 1232 using the measurement part 1241 and the determining part 1242 will be described. Here, the case where the measurement part 1241 is the weight measurement part will be described as an example. Here, for convenience of explanation, the reference numeral of the weight measurement part is the same as that of the measurement part.

The determination part 1242 receives a weight measured in real time from the weight measurement part 1241 and compares the transferred measured weight with the preset reference weight. Thus, the determination part 1242 maintains the valve 1232 in a closed state if the measured weight is less than the reference weight. Thus, the mixture in the third container 1213 is not discharged. However, when the measured weight is greater than or equal to the reference weight, the determination part 1242 opens the valve 1232. Thus, the mixture in the third container 1213 is discharged to the separation part.

In the above, the case in which the measurement parts 1132a-1 and 1132b-1 are the weight measurement parts has been described as an example. However, the measurement part is not limited thereto and may be the height sensor. The measurement parts 1132a-1 and 1132b-1 are not limited thereto and may be units of measuring things other than the weight and height.

In the above, it has been explained that the ruthenium P is collected by opening the valve 1232 to discharge the mixture in the third container 1213 to the separation part 1220. However, it is not limited thereto, and the third container 1213 itself may be separated from the body 1211, and the ruthenium P may be separated and collected from the mixture in the separated third container 1213.

In addition, in the above description, the coolant used in the first collector 1100 is referred to as the first coolant, and the coolant used in the second collector 1200 is referred to as the second coolant C. Here, the first coolant and the second coolant C may be the same or different. That is, when using a liquid as the first coolant, the first coolant may be the same liquid as the second coolant C. Even if the liquid is used as the first coolant, different types of liquids may be used for the first coolant and the second coolant C.

In addition, the configuration including the collecting device 1000 and the process device 10 as described above may be defined as a substrate processing apparatus. That is, the substrate processing apparatus may include the process device 10 that processes the substrate and the collecting device that collects the precursor from the exhaust gas discharged from the process device 10.

Hereinafter, with reference to FIGS. 1 to 5, the operation of the collecting device in accordance with an exemplary embodiment will be described. Here, contents duplicated with the contents described above are briefly explained or omitted.

The exhaust gas discharged from the process device 10 is introduced first into the housing part 1110 of the first collector 1100. In addition, the exhaust gas G is cooled while passing through the inside of the housing part 1110. That is, the exhaust gas discharged from the process device 10 sequentially passes through the first housing 1111, the connection housing 1113, and the second housing 1112.

Here, the exhaust gas passing through the inside of the housing part 1110 is cooled by the cooling part 1120 installed inside the housing part 1110. That is, while the exhaust gas sequentially passes through the first housing 1111, the connection housing 1113, and the second housing 1112, the exhaust gas is cooled by the first cooling part 1120a installed in the first housing 1111, the plurality of partition walls 1150a and 1150b installed in the connection housing 1113, and the second cooling part 1120b installed in the second housing 1112. Here, the exhaust gas may be cooled to a temperature of approximately 10° C. or less in each of the first housing 1111, the connection housing 1113, and the second housing 1112. Thus, ruthenium contained in the exhaust gas G is cooled to be powdered. That is, ruthenium is recovered from the exhaust gas G. The ruthenium P recovered from the housing part 1110 is collected into the first and second containers 1132a and 1132b disposed therebelow (first collection process).

The exhaust gas G discharged from the second housing 1112 of the first collector 1100 is supplied into the body 1211 of the second collector 1200. The exhaust gas supplied into the body 1211 is cooled by the second coolant C injected into the body 1211. Here, the exhaust gas G may be cooled by the second coolant C. Thus, ruthenium contained in the exhaust gas G is cooled, and thus, ruthenium contained in the exhaust gas is transformed into powder. That is, ruthenium is recovered from the exhaust gas G. The ruthenium P recovered from the body 1211 is collected into the third container 1213 disposed therebelow. In addition, the second coolant C injected into the body 1211 is collected in the third container 1213. Here, the ruthenium P is precipitated in the second coolant C collected in the third container. Thereafter, a mixture containing ruthenium P and the second coolant C contained in the third container 1213 is supplied to the separation part 1220. The separation part 1220 separates the ruthenium P from the mixture (secondary collection process). That is, the ruthenium P precipitated in the second coolant C is separated.

Next, the ruthenium P collected in the first and second containers 1132a and 1132b of the first collector 1100 and the ruthenium P separated in the separation part 1220 of the second collector 1200 are processed. That is, the ruthenium P collected in the first and second collectors 1100 and 1200 is processed to be used again in the process device. For example, the ruthenium P collected in the first and second collectors 1100 and 1200 is processed and manufactured into a gas. That is, a precursor is manufactured. The precursor prepared in this manner may be recycled in the process device.

In the above, it has been explained that the collecting device 1000 in accordance with an exemplary embodiment collects ruthenium from the exhaust gas G containing ruthenium. However, it is not limited thereto, and various noble metal precursors may be applied. For example, the collecting device in accordance with an exemplary embodiment collects at least one precursor of ruthenium (Ru), silver (Ag), gold (Pt), palladium (Pd), rhodium (Rh), iridium (Ir), and osmium (Os) from the exhaust gas G.

In the collecting device in accordance the exemplary embodiments, the precursor may be effectively collected from the exhaust gas discharged from the process device 10. That is, collection efficiency of the precursor collected from the exhaust gas G may be improved. Thus, an amount of precursor to be discarded may be reduced. In addition, the collected precursor may be recycled again in the process device to reduce costs due to the precursor.

### INDUSTRIAL APPLICABILITY

In accordance with the exemplary embodiments, the precursor may be effectively collected from the exhaust gas discharged from the process device. That is, the collection efficiency of the precursor collected from the exhaust gas may be improved. Therefore, the amount of precursor to be discarded may be reduced. In addition, the collected precursor may be recycled again in the process device to reduce the costs due to the precursor.

1. A collecting device, which collects a precursor from an exhaust gas discharged from a process device using the precursor, the collecting device comprising:
a first collector provided with a cooling part, through which a first coolant passes, so the exhaust gas is cooled to be recovered and having an internal space connected to the process device so as to be adjusted to a vacuum pressure.

2. The collecting device of claim 1, further comprising a second collector provided with an injection member configured to inject a second coolant to the exhaust gas and disposed at one side of the first collector.

3. The collecting device of claim 2, wherein the first collector is installed between one end of a pump connected to the process device and the process device, and
the second collector is connected to the other end of the pump.

4. The collecting device of claim 3, wherein the cooling part comprises a body and a passage provided in the body so that the first coolant passes therethrough, and
wherein the body comprises:
a first body extending upward; and
a plurality of second bodies disposed to be spaced apart from each other in a vertical direction on an outer surface of the first body.

5. The collecting device of claim 4, wherein the plurality of second bodies disposed adjacent to each other in the vertical direction are disposed to be misaligned in a horizontal direction.

6. The collecting device of claim 4, wherein each of the second bodies is provided to be inclined so that a height thereof decreases as it moves away from the first body.

7. The collecting device of claim 4, wherein the first collector comprises:
a housing part in which the cooling part is installed therein;
an accommodation part connected to a lower portion of the housing part to accommodate the precursor recovered from the housing part; and
an opening/closing part installed in the housing part so as to be disposed between the cooling part and the accommodation part.

8. The collecting device of claim 7, wherein the accommodation part comprises:
a body connected to a lower portion of the housing part; and
a container having an internal space in which the recovered precursor is accommodated and installed inside the body, and
the first collector comprises:
a measurement part configured to detect the precursor accommodated in the container; and
a determination part configured to determine whether replacement of the container is required depending on a measured value measured in the measurement part.

9. The collecting device of claim 7- or 8, wherein the housing part comprises:
a first housing connected to the process device; and
a second housing connected to the first housing in a horizontal direction so as to communicate with the first housing,
wherein the second housing is configured to connect the first housing to the pump, and
the cooling part is installed in each of the first housing and the second housing.

10. The collecting device of claim 9, wherein the housing part comprises a connection housing configured to connect the first housing to the second housing, and
the first collector comprises a partition wall installed inside the connection housing, the partition wall having a passage through which the first coolant flows and being configured to partially shield an interior of the connection housing.

11. The collecting device of claim 10, wherein the partition wall is provided in plurality, and
the plurality of partition walls are disposed at different positions inside the connection housing.

12. The collecting device of claim 2, wherein the second collector comprises:
a body having an internal space, in which the second coolant injected from the injection member is accommodated, and the injection member is installed; and
a container disposed below the injection member to accommodate the precursor, which is recovered from the exhaust gas inside the body, and the second coolant.

13. The collecting device of claim 12, wherein the second collector comprises:
a measurement part configured to detect the precursor and the second coolant, which are accommodated in the container; and
a determination part configured to whether to discharge the precursor and the second coolant, which are accommodated in the container, depending on a measured value measured in the measurement part.

14. The collecting device of claim 12, wherein an outlet communicating with a scrubber to discharge the exhaust gas is provided in an end of the body, and
the second collector comprises a blocking member installed inside the body to face the outlet so that the second coolant injected into the body is discharged through the outlet.

15. The collecting device of claim 14, wherein the blocking member is installed between the injection member and the outlet, and
the blocking member is installed to be inclined so that a height thereof decreases from the outlet toward the injection member.

16. A substrate processing apparatus comprising:
a chamber having an internal space;
a support configured to support a substrate inside the chamber;
a supply part configured to supply a gas containing a precursor into the chamber; and
a first collector provided with a cooling part, through which a first coolant passes, to recovery the precursor contained in an exhaust gas discharged from the chamber and having an internal space communicating with the chamber so as to be adjusted to a vacuum pressure.

17. The substrate processing apparatus of claim 16, further comprising a second collector provided with an injection member configured to inject a second coolant to the exhaust gas and disposed at one side of the first collector.

18. The substrate processing apparatus of claim 17, further comprising a pump installed between the first collector and the second collector to adjust a pressure of the chamber and the first collector to a vacuum pressure.

19.-26. (canceled)

27. The collecting device of claim 8, wherein the housing part comprises:
a first housing connected to the process device; and
a second housing connected to the first housing in a horizontal direction so as to communicate with the first housing,
wherein the second housing is configured to connect the first housing to the pump, and
the cooling part is installed in each of the first housing and the second housing.
